(19) United States
(12) Patent Application Publication
(10) Pub. No.: US 2015/0277792 A1
(43) Pub. Date: Oct. 1, 2015

(54) MEMORY CONTROLLER, MEMORY SYSTEM, AND RELATED METHOD OF OPERATION

(71) Applicants: JIN-HEE MA, SEOUL (KR); SE-HWAN LEE, SEOUL (KR); DA-WOON JUNG, HWASEONG-SI (KR); MOON-WOOK OH, SEOUL (KR)

(72) Inventors: JIN-HEE MA, SEOUL (KR); SE-HWAN LEE, SEOUL (KR); DA-WOON JUNG, HWASEONG-SI (KR); MOON-WOOK OH, SEOUL (KR)

(21) Appl. No.: 14/338,361

(22) Filed: Jul. 23, 2014

(30) Foreign Application Priority Data
Mar. 26, 2014 (KR) 10-2014-0035369

(51) Int. Cl. G06F 3/06; G11C 16/04; G11C 16/10

(52) U.S. Cl. CPC G06F 3/0619; G06F 3/0679; G06F 3/065; G06F 3/0655; G11C 16/107; G11C 16/0483; G06F 2206/1014

(57) ABSTRACT

A method of controlling a non-volatile memory device comprises detecting a bad page in a first block of the non-volatile memory device, and as a consequence of detecting the bad page, copying meta data stored in valid pages of the first block and original meta data corresponding to the bad page, programming the copied meta data to a second block of the non-volatile memory device, erasing the first block, and thereafter programming user data in the first block.

### CROSS-REFERENCE TO RELATED APPLICATION

This application claims priority under 35 U.S.C. §119 to Korean Patent Application No. 10-2014-0035369 filed on Mar. 26, 2014, the subject matter of which is hereby incorporated by reference.

### BACKGROUND OF THE INVENTION

The inventive concept relates generally to methods of operating a memory controller and memory systems comprising a memory controller.

Semiconductor memory devices can be roughly divided into two categories according to whether they retain stored data when disconnected from power. These categories include volatile memory devices, which lose stored data when disconnected from power, and non-volatile memory devices, which retain stored data when disconnected from power. Examples of volatile memory devices include dynamic random access memory (DRAM) and static random access memory (SRAM), and examples of non-volatile memory devices include read only memory (ROM), magnetoresistive random access memory (MRAM), resistive random access memory (RRAM), and flash memory.

Due to an ever increasing demand for non-volatile data storage, researchers are engaged in continual efforts to develop non-volatile memory devices with smaller size and improved performance. Unfortunately, as non-volatile memory devices become smaller, their operating tolerances tend to decrease, along with their reliability. In an effort to reduce the chance of malfunction due to diminished reliability, some devices attempt to identify memory cells with diminished operating capability and then disable those memory cells. This can be problematic, however, since disabling memory cells decreases overall storage capacity. Accordingly, under these circumstances there is a general tradeoff to be made between reliability and storage capacity.

### SUMMARY OF THE INVENTION

In one embodiment of the inventive concept, a method of controlling a non-volatile memory device comprises detecting a bad page in a first block of the non-volatile memory device, and as a consequence of detecting the bad page, copying meta data stored in valid pages of the first block and original meta data corresponding to the bad page, programming the copied meta data to a second block of the non-volatile memory device, erasing the first block, and thereafter programming user data in the first block.

In another embodiment of the inventive concept, a method of controlling a non-volatile memory device comprises identifying a bad page of the non-volatile memory device based on a program or read failure, determining a type of data associated with the bad page, and selectively performing bad page management or bad block management according to the determined type of data.

In still another embodiment of the inventive concept, a memory system comprises a non-volatile memory device comprising memory cell array stacked on a substrate and comprising at least one meta data block and at least one user data block, and a memory controller that controls the non-volatile memory device, the memory controller comprising a bad area management unit configured to manage a bad area of both the at least one meta data block and the at least one user data block, wherein the bad area management unit is configured to convert a designated meta data block among the at least one meta data block into a user data block as a consequence of detecting a bad page in the designated meta data block.

These and other embodiments of inventive concept can potentially increase the amount of useful data storage space provided by one or more non-volatile memory devices while preserving reliability.

### BRIEF DESCRIPTION OF THE DRAWINGS

Embodiments of the inventive concept are described below with reference to the accompanying drawings. These embodiments are presented as teaching examples and should not be construed to limit the scope of the inventive concept.

FIG. 1 is a block diagram illustrating a memory system according to an embodiment of inventive concept.

FIG. 2 is a conceptual diagram illustrating logical pages of a 3-bit multi-level cell (MLC) flash memory device according to an embodiment of the inventive concept.

FIG. 3 is a block diagram illustrating a memory controller in the memory system of FIG. 1 according to an embodiment of the inventive concept.

FIG. 4 is block diagram of a non-volatile memory device in the memory system of FIG. 1 according to an embodiment of the inventive concept.

FIG. 5 is a conceptual diagram illustrating a method of operating a bad area management unit according to an embodiment of inventive concept.

FIG. 6 is a conceptual diagram illustrating a free block table in the memory controller of FIG. 3 according to an embodiment of the inventive concept.

FIG. 7 is a diagram illustrating a memory cell array in the memory system of FIG. 1 according to an embodiment of inventive concept.

FIG. 8 is a perspective view of a part of a memory block in FIG. 7 according to an embodiment of the inventive concept.

FIG. 9 is a cross-sectional view taken along a line XV-XV′ in FIG. 7.

FIG. 10 is an equivalent circuit diagram of a memory block described with reference to FIGS. 7 through 9.

FIG. 11 is a flowchart illustrating a method of operating a memory controller according to an embodiment of the inventive concept.

FIG. 12 is a flowchart illustrating a method of operating a memory controller according to an embodiment of the inventive concept.

FIG. 13 is a block diagram of an electronic device comprising a memory system according to an embodiment of inventive concept.

FIG. 14 is a block diagram of an electronic device comprising a memory system according to an embodiment of inventive concept.

FIG. 15 is a block diagram of an electronic device comprising a memory system according to an embodiment of inventive concept.

FIG. 16 is a block diagram of an electronic device comprising a memory system according to an embodiment of inventive concept.

FIG. 17 is a block diagram of an electronic device comprising a memory system according to an embodiment of inventive concept.

FIG. 18 is a block diagram of an electronic device comprising a memory system according to an embodiment of inventive concept.

### DETAILED DESCRIPTION

Embodiments of the inventive concept are described below with reference to the accompanying drawings. These embodiments are presented as teaching examples and should not be construed to limit the scope of the inventive concept.

In the description that follows, the terms first, second, etc. may be used to describe various features, but the described features should not be limited by these terms. Rather, these terms are used merely to distinguish between different features. For example, a first element could be termed a second element, and, similarly, a second element could be termed a first element, without departing from the scope of this disclosure. As used herein, the term “and/or,” includes any and all combinations of one or more of the associated listed items.

Where a feature is referred to as being “connected,” or “coupled,” to another feature, it can be directly connected or coupled to the other feature or intervening features may be present. In contrast, where a feature is referred to as being “directly connected,” or “directly coupled,” to another feature, there are no intervening features present. Other words used to describe the relationship between features should be interpreted in a like fashion (e.g., “between,” versus “directly between,” “adjacent,” versus “directly adjacent,” etc.).

The terminology used herein is for the purpose of describing particular embodiments only and is not intended to be limiting. As used herein, the singular forms “a,” “an,” and “the,” are intended to include the plural forms as well, unless the context clearly indicates otherwise. It will be further understood that the terms “comprises,” “comprising,” “includes,” and/or “including,” where used herein, specify the presence of stated features but do not preclude the presence or addition of one or more other features. In some alternative embodiments, illustrated functions/acts may occur out of the order shown in the figures. For example, two operations shown in succession may in fact be performed substantially concurrently or may sometimes be performed in a reverse order, depending upon the functionality/acts involved.

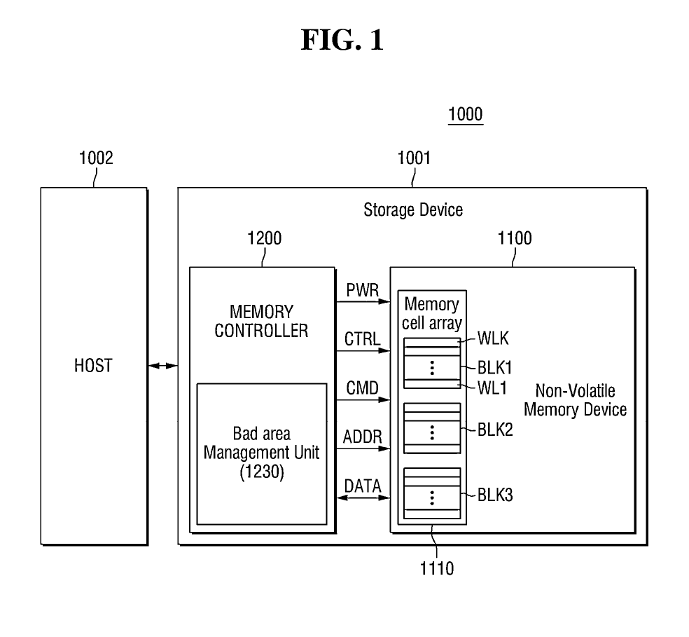

FIG. 1 is a block diagram illustrating a memory system 1000 according to an embodiment of inventive concept. Memory system 1000 be embodied in, e.g., an electronic device such as a mobile phone, a smart phone, a tablet, a PC, a personal digital assistant (PDA), an enterprise digital assistant (EDA), a digital still camera, a digital video camera, a portable multimedia player (PMP), a personal navigation device or portable navigation device (PDN), a handled game console, or an e-book.

Referring to FIG. 1, memory system 1000 comprises a storage device 1001 and a host 1002. Storage device 1001 comprises a non-volatile memory device 1100 and a memory controller 1200. Host 1002 provides original data to memory controller 1200.

Memory controller 1200 controls non-volatile memory device 1100, e.g., to perform an erase, program or read operation. To perform the operation, non-volatile memory device 1100 receives a command CMD, an address ADDR and data DATA through an input/output line. Non-volatile memory device 1100 receives power through a power line and a control signal CTRL through a control line. Control signal CTRL may comprise a command latch enable CLE, an address latch enable ALE, a chip enable nCE, a write enable nWE, a read enable nRE, etc.

Non-volatile memory device 1100 may comprise, e.g., a flash memory, an electrically erasable programmable read only memory (EEPROM), a ferroelectric random access memory (FRAM), a phase change RAM (PRAM), a magneto resistive RAM (RAM), etc. A NAND flash memory device is illustrated in FIG. 1 as an example, but the inventive concept is not limited thereto. Non-volatile memory device 1100 may serve as a storage unit to store data provided from memory controller 1200.

Non-volatile memory device 1100 comprises memory cell arrays configured to store data. Each of the memory cell arrays comprises blocks, BLK1 through BLK3, and each of blocks BLK1 through BLK3 comprises word lines WL1 through WLk (‘k’ being a natural number). Each of blocks, BLK1 through BLK3 constitutes a separate “erase unit”. In other words, during an erase operation, all memory cells of an identified block are erased in response to a single erase command (e.g., simultaneously erased). Each block may be configured to store either meta data generated by memory controller 1200 or user data provided from host 1002.

Each word line may be designated as a “read/program unit” during both program and read operations, such that all memory cells connected to the designated word line are programmed during the program operation and read during the read operation (e.g., simultaneously programmed or read). In MLC non-volatile memory device 1100, each word line comprises multiple logical pages. The memory cells of a given set of blocks may be arranged in a three dimensional (3D) structure where memory cells are vertically stacked on a substrate extending primarily in at least one horizontal direction. In this context, the terms “vertical” and “horizontal” are used to denote relative orientations.

It is assumed that non-volatile memory device 1100 comprises one or more “bad area(s)” that result from defects in the fabrication of the constituent components forming the memory cells of one or more blocks, and/or erroneous operating conditions (e.g., column fail, disturbance, wear-out, etc.). In this context, a “bad area” may comprise an area where program or erase operation is failed and variously sized (and/or designated within operating methods consistent with the described embodiments) ranging from a single word line comprising the bad memory cell to an entire memory block designated as a bad memory block because it contains one or more bad memory cells.

Memory controller 1200 comprises a bad area management unit 1230, which is configured to selectively manage one or more areas in the available memory space provided by non-volatile memory device 1100 as a bad area. For example, bad area management unit 1230 is configured to designate a bad page where program or read operation is failed. Bad area management unit 1230 checks a type of data stored in the bad page. It is assumed that the type of data is either meta data or user data.

Where data of the bad page is meta data, bad area management unit 1230 performs bad block management. For example, the first block comprising the bad page may be copied and the copied data may be programmed into the second block. Then, the first block may be erased and become the free block to store not meta data but user data. Meta data may be generated by memory controller 1200 to manage non-volatile memory device 1100. Thus, meta data comprises, for example, address mapping information. On the other hand, where data of the bad page is user data, bad area management unit 1230 performs bad page management. Thus, the bad page in the first block is marked as invalid page and the bad page is discarded. In this manner, bad area management unit 1230 may effectively increase the available data storage capacity provided by the memory cell array(s) of non-volatile memory device 1100 by minimizing or reducing the size of designated bad areas. Operation of a bad area management unit 1230 will be described in some additional detail with reference to FIG. 3.

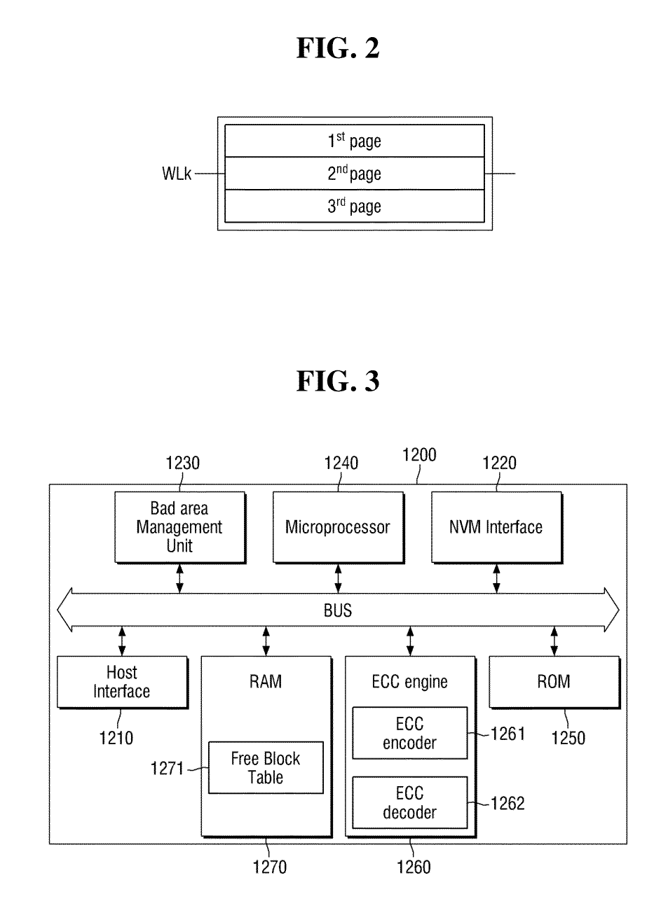

FIG. 2 is a conceptual diagram illustrating logical pages of a 3-bit MLC flash memory device. In an MLC non-volatile memory, 2^{k} threshold voltages are used to program k bits in each memory cell. Threshold voltages of memory cells where the same data is programmed may form a threshold voltage distribution of a specific range because of relatively small differences in the electrical characteristics of different memory cells. Each of the threshold voltage distributions can correspond to each of 2^{k} data values that can be generated by k bits.

In a 3-bit MLC, seven threshold voltage distributions (P1, P2, . . . , P7) of a programmed state and one threshold voltage distribution E of an erased state are formed. In a 3-bit MLC, one word line comprises three logical pages as illustrated in FIG. 2. Thus, data stored in the three logical pages may form seven programmed states and one erased state.

FIG. 3 is a block diagram further illustrating one example of memory controller 1200 of FIG.1. Here, memory controller 1200 comprises a host interface 1210, a memory interface 1220, a bad area management unit 1230, microprocessor 1240, a read-only memory (ROM) 1250, and an error detection and correction (ECC) engine 1260, and a random access memory (RAM) 1270,respectively interconnected via a bus.

Host interface 1210 provides an interface between memory controller 1200 and host 1002. For example, host interface 1210 may communicate a logical address, a command latch enable (CLE) signal, an address latch enable (ALE) signal, a ready and busy (R/B) signal, a chip enable (CE) signal from the host to memory controller 1200. In certain embodiments, host interface 1210 communicates with host 1002 using one or more predetermined data communication protocol(s), such as universal serial bus (USB), small computer system interface (SCSI), PCI express, ATA, parallel ATA (PATA), serial ATA (SATA), and serial attached SCSI (SAS).

Memory interface 1220 may be used to exchange data/address/control information between memory controller 1200 and non-volatile memory device 1100. Also, a command from microprocessor 1240 may be communicated to non-volatile memory device 1100 via memory interface 1220. Bad area management unit 1230 controls bad block management based on the type of data such as meta data or user data where the bad page is generated.

Microprocessor 1240 controls operations of memory system 1000 and may comprise, for example, circuitry, logic circuitry, and/or enabling software code. Where power is applied to memory system 1000, microprocessor 1240 may be used to control the boot-up of memory system 1000. Microprocessor 1240 may be used to interpret command(s) received via host interface 1210, and to thereafter control the operation of non-volatile memory device 1100 based on the interpretation results. Microprocessor 1240 may also perform mapping operation that transfers a logical address provided from the host to a corresponding physical address of non-volatile memory device 1100 using one or more address mapping table(s).

ROM 1250 may be used to store a firmware for driving memory system 1000. The firmware may be stored, wholly or in part, in non-volatile memory device 1100 as well as ROM 1250. Accordingly, control operations performed by microprocessor 1240 may be executed in accordance with the firmware stored in ROM 1250 and/or non-volatile memory device 1100.

ECC engine 1260 may be configured to perform one or more error detection and/or correction (ECC) routines on data being exchanged between memory controller 1200 and non-volatile memory device 1100. ECC engine 1260 may be configured to perform error bit correction and comprise ECC decoder 1262 and ECC encoder 1261. ECC decoder 1262 and ECC encoder 1261may perform error bit correction.

ECC encoder 1261 may be used to generate and add ECC data (e.g., parity data) to program data to be stored in non-volatile memory device 1100. Thereafter, ECC decoder 1262 may be used to perform error correction decoding on read data provided from non-volatile memory device 1100 using the ECC data. Corrected (as needed) read data is then communicated to the host via memory controller 1200. ECC decoder 1262 is configured to perform error correction decoding on output data, determine whether the error correction decoding is successful based on the result of the error correction decoding, and outputs an instruction signal based on the decoding result. Read data may be transmitted to ECC decoder 1262, and ECC decoder 1262 may correct error bits of the data using the parity bits. Where the number of error bits exceeds a predetermined limit that can be corrected, ECC decoder 1262 cannot correct the error bits, resulting in an error correction failure. ECC encoder 1261 and ECC decoder 1262 may perform error correction using, but not limited to, low density parity check (LDPC) code, BCH code, turbo code, Reed-Solomon code, convolution code, recursive systematic code (RSC), or coded modulation such as trellis-coded modulation (TCM) or block coded modulation (BCM), etc.

RAM 1270 functions within memory controller 1200 as a buffer memory to temporarily store incoming/outgoing data as well as received command/address information as received via host interface 1210. Bad area management unit 1230 may be used to store “program data” to be programmed to non-volatile memory device 1100 during a program operation, and “read data” retrieved from non-volatile memory device 1100 during a read operation. Bad area management unit 1230 may also be used to store various parameter values and variable values for memory controller 1200 as well as non-volatile memory device 1100. The types of data to be programmed to non-volatile memory device 1110 comprise at least both meta data which is generated by memory controller 1200 in order to manage non-volatile memory device 1100 and user data provided from host 1002. Meta data may comprise information of address mapping table which is used to transfer logical address to physical address corresponding to non-volatile memory device 1100. Moreover, bad area management unit 1230 may comprise free block table which indicates free block information of non-volatile memory device 1100.

Bad area management unit 1230 selectively manages identified bad area(s) within the memory space provided by non-volatile memory device 1100. Bad area management unit 1230 may be configured to check program failed or read failed page. Bad area management unit 1230 determines the type of data such as meta data or user data, and it determines whether a bad page management or a bad block management is performed based on the type of data. For example, bad area management unit 1230 may be configured to perform the bad block management where data of the bad page is meta data. Therefore, bad area management unit 1230 may be configured to copy data of the first block comprising the bad page to the second block and erase the first block. In other words, bad area management unit 1230 may copy and program meta data stored in normal pages of the first block and original meta data corresponding to the bad page. The erased first block may become free block where user data is programmed. Therefore, information of the erased first block may be updated into RAM 1270. In meta data programming, address mapping is not needed. However, information which indicates that the second block is meta data block may be stored into RAM 1270 or non-volatile memory device 1100. The erased first block may become the free block in order to store user data, not meta data. Therefore, the bad area management unit 1230 is configured to transfer the meta data block to the user data block where a bad page occurs in the meta data block.

The bad page is either a read failed page or a program failed page. Meta data is generated by memory controller 1200 in order to manage non-volatile memory device 1110. Thus, meta data is inevitable information and need to be stored into the stable block. Assuming that the bad page is read failure such as ECC decoding failure, meta data stored in the first block is identically stored in the third block. Thus, bad area management unit 1230 may copy normal page data of the first block and the original data stored in the third block corresponding to the bad page of the first block. And bad area management unit 1230 may program copied data into the second block.

Assuming that the bad page is program failure, the original data provided from host 1002 is temporarily stored in RAM 1270. Thus, bad area management unit 1230 copies normal page data of the first block and the original data stored in RAM 1270 corresponding to the bad page of the first block. And bad area management unit 1230 may program copied data into the second block. In another example, bad area management unit 1230 performs the bad page management where data in the bad page is user data. It is assumed that the program failure page happens. The program failure is caused by a failure of a verify operation. Bad area management unit 1230 may make the bad page invalid. Thus, the bad page is discarded. Then, bad area management unit 1230 may program the original data in RAM corresponding to the bad page to the page or word line adjacent to the bad page. Under the control of microprocessor 1240, bad area management unit 1230 may perform page mapping operation and update newly programmed page information to mapping table.

It is assumed that the read failure page such as ECC decoding failure happens where the data of bad page is user data. Under these circumstances, bad area management unit 1230 discards the bad page. Thus bad area management unit 1230 of FIG. 3 may be configured to treat a sub-block of the target memory block (i.e., a bad word line being connected to an impaired bad memory cell) as a bad area, or to treat the entire target block as a bad area based on the type of stored data. Such selective identification and classification of individual treatment of bad memory cells enables a more efficient designation of bad areas within a memory cell array, thereby preserving more available memory space for use within the constituent memory system.

As shown in FIGS. 1 and 3 hereafter, non-volatile memory device 1100 may in certain embodiments be implemented in a 3D structure.

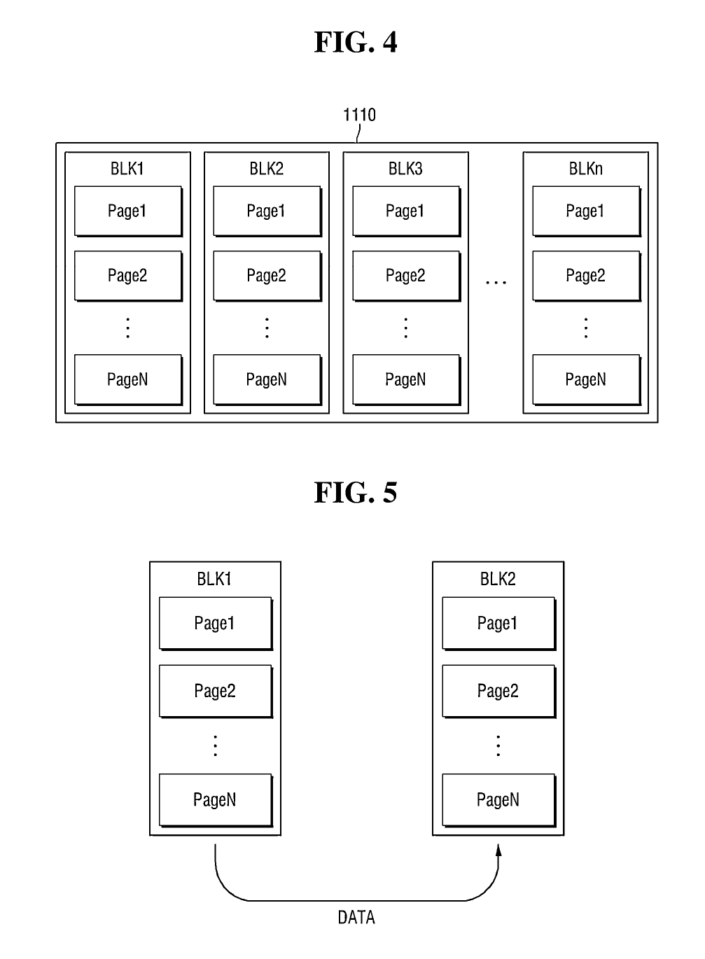

FIG. 4 is detailed block diagram of non-volatile memory device in FIG. 1, according to an embodiment of the inventive concept. In this embodiment, memory cell array 1110 comprises multiple blocks BLK1 through BLKN and the block comprises pages, page1 through pageN. In case of MLC non-volatile memory device, multiple logical pages may correspond to one physical word line.

FIG. 5 is a conceptual diagram illustrating the operating method of a bad area management according to an embodiment of inventive concept.

Referring to FIGS. 3 through FIG.5, there is first block, BLK1 where meta data is stored and there is second block, BLK2 that is a free block. It is assumed that the second page of the first block is read. Read data of the second page is transferred to ECC decoder 1262. ECC decoder 1262 performs error correction operation. Where ECC decoder 1262 fails to correct error bits, bad area management unit 1230 determines whether data of the second page is user data or meta data. It is assumed that data of the second page is meta data. Therefore, bad area management unit 1230 copies data of the first block comprising the second page into the second block that is free block. Then, the second block stores meta data. The first block is erased after copy operation and becomes free block where user data can be stored. In case of meta data, meta data of the first block may identically be stored in the third block. Thus, bad area management unit 1230 may be read the same data of the bad page, the second page of the first block from the third block and copy the read data into the second block.

In addition, bad area management unit 1230 may not copy data of the bad page and transfer data of the first block except that of the bad page into the second block. Where meta data of the second block is read, the microprocessor reads data of the third block which is the same data as that of bad page and copies the read data to the second block.

Where a program operation fails, bad area management unit 1230 copies data of the first block into the second block. Bad area management unit 1230 may use the original data in RAM corresponding to the bad page data and copy the original data into the second block.

Information of the first block that becomes the free block may be updated to a free block mapping table. Free block table 1271 may be stored in bad area management unit 1230. Meta data is not derived from host 1002 and is generated by the memory controller in order to manage non-volatile memory device 1100. Therefore, it is unnecessary to perform address mapping to convert a logical address into a physical address where meta data is programmed.

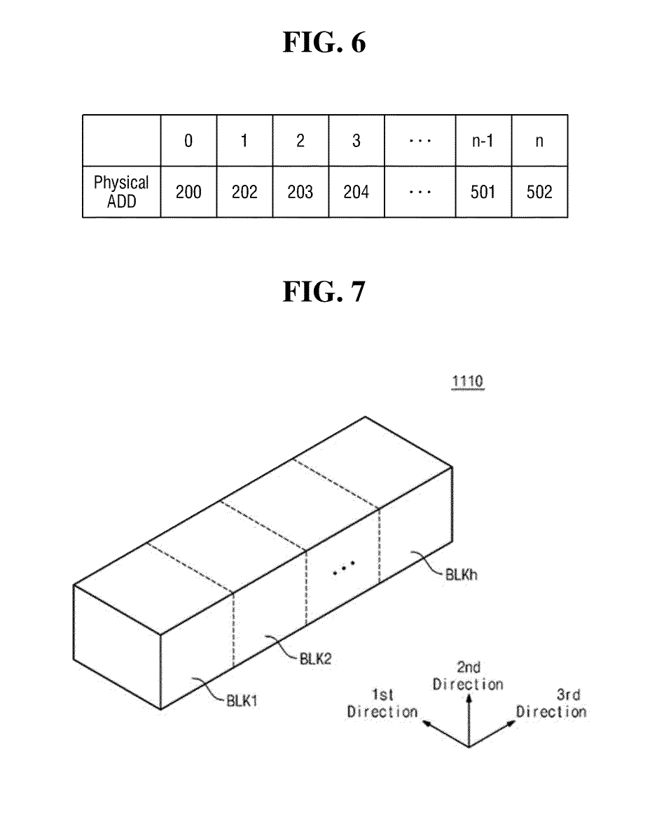

FIG. 6 is a conceptual diagram illustrating the free block table in FIG.3 according to an embodiment of the inventive concept. The free block table shows multiple physical addresses of free blocks corresponding to non-volatile memory device 1100.

Referring FIGS. 3 through 6, where a bad page is detected in the first block where meta data is stored, the first block is erased. The erased first block becomes the free block and is updated into the free block table. The updated free block may store user data.

As shown in FIGS. 7 to 10, non-volatile memory device 1100 may have a three-dimensional structure.

FIG. 7 is a diagram illustrating a memory cell array in FIG. 1 according to an embodiment of the inventive concept.

Referring to FIG. 7, a memory cell array may comprise memory blocks BLK1 through BLKh, each of which is formed to have a three-dimensional structure (or, a vertical structure). For example, each of the memory blocks BLK1 through BLKh may comprise structures extending along first to third directions.

Each of the memory blocks BLK1 through BLKh may comprise multiple NAND strings extending along the second direction. For example, multiple NAND strings NS may be provided along the first and third directions. Each NAND string NS may be connected to a bit line, at least one string selection line, at least one ground selection line, word lines, and a common source line. That is, each memory block may be connected to multiple bit lines, multiple string selection lines, multiple ground selection lines, multiple dummy word lines, and multiple common source lines. Each memory block will be more fully described with reference to FIG. 7 through FIG. 10.

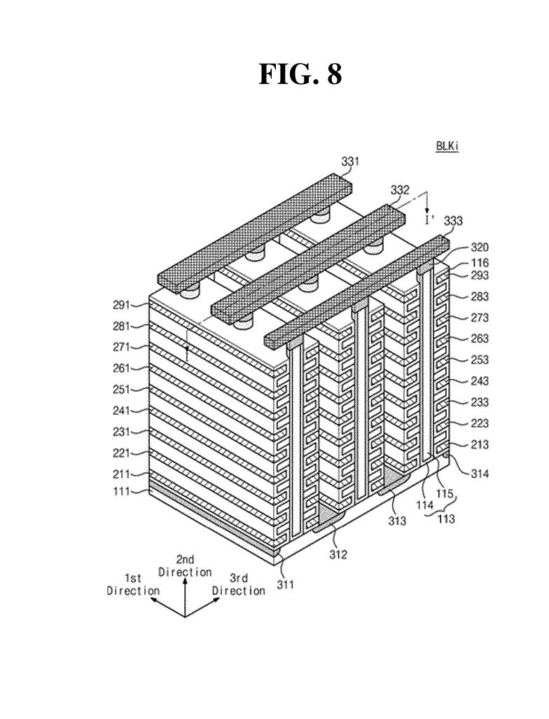

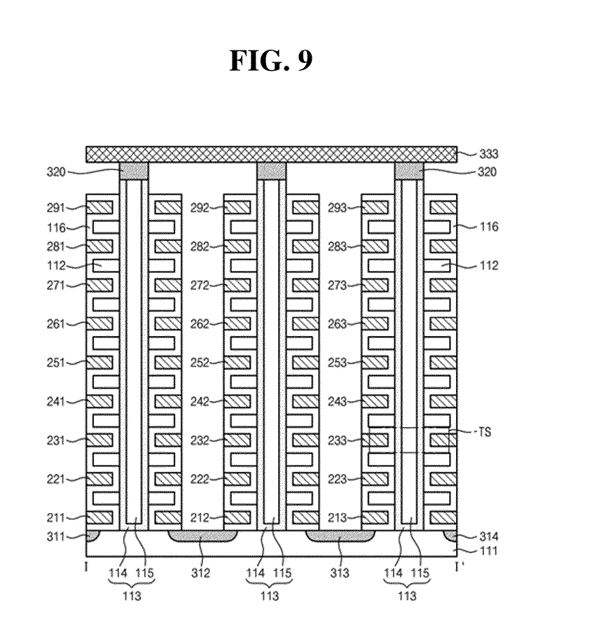

FIG. 8 is a perspective view of a part of a memory block in FIG. 7 according to an embodiment of the inventive concept, and FIG. 9 is a cross-sectional view taken along a line XV-XV′ of FIG. 7. Referring to FIGS. 8 and 9, a memory block BLKi may comprise structures that extend along first to third directions.

First, a substrate 111 is provided. Substrate 111 may comprise a silicon material doped with a first-type impurity, for example. In some embodiments, substrate 111 comprises a silicon material doped with a p-type impurity or a p-well (or, a pocket p-well), and may further comprise an n-well surrounding the p-well. Below, it is assumed that substrate 111 is p-type silicon. However, substrate 111 is not limited thereto.

First through fourth doping regions 311 through 314 extending along the first direction may be provided at substrate 111. For example, first through fourth doping regions 311 through 314 may be n-type. Hereinafter, it is assumed that the first through fourth doping regions 311 through 314 are an n-type. However, the first through fourth doping regions 311 through 314 are not limited thereto.

On substrate 111 between the first and second doping regions 311 and 312, insulating materials 112 extending along the first direction may be sequentially provided along the second direction. For example, insulating materials 112 and substrate 111 may be spaced apart along the second direction. For example, insulating materials 112 may be formed to be separated by a desired (or alternatively predetermined) distance along the second direction. In some embodiments, insulating materials 112 may comprise an insulating material such as silicon oxide.

On substrate 111 between the first and second doping regions 311 and 312, pillars 113 may be provided which are sequentially disposed along the first direction and pass through insulating materials 112 along the second direction. In some embodiments, pillars 113 make contact with substrate 111 through insulating materials 112, respectively.

In some embodiments, each of pillars 113 is formed of multiple different materials. For example, a surface layer 114 of each of pillars 113 may comprise a first-type silicon material. For example, surface layer 114 of each of pillars 113 may comprise a silicon material doped with the same type as substrate 111. Hereinafter, it is assumed that surface layer 114 of each of pillars 113 comprises p-type silicon, although it is not limited thereto.

An inner layer 115 of each of pillars 113 may be formed of an insulating material. For example, inner layer 115 of each of pillars 113 may comprise an insulating material such as silicon oxide, but example embodiments of inventive concepts are not limited thereto.

Between the first and second doping regions 311 and 312, an insulating film 116 may be provided along exposed surfaces of substrate 111, insulating materials 112, and pillars 113. For example, the thickness of insulating film 116 may be less than half a distance between insulating materials 112. That is, a region where a material other than insulating materials 112 and insulating film 116 is disposed may be provided between an insulating film 116 provided on a lower surface of a first insulating material among insulating materials 112 and an insulating film 116 provided on an upper surface of a second insulating material and at the lower portion of the first insulating material.

Between the first and second doping regions 311 and 312, conductive materials 211 through 291 may be provided on an exposed surface of insulating film 116. For example, one of conductive materials 211 extending along the first direction may be provided between substrate 111 and insulating materials 112 adjacent to substrate 111. In detail, one of conductive materials 211 extending along the first direction may be provided between substrate 111 and insulating film 116 at a lower surface of the insulating material adjacent to substrate 111.

A conductive material extending along the first direction may be provided between an insulating film 116 on an upper surface of a specific insulating material of insulating materials 112 and an insulating film 116 on a lower surface of an insulating material disposed at a top of the specific insulating material.

Conductive materials 221 through 281 extending along the first direction may be provided among insulating materials 112. Further, a conductive material 291 extending along the first direction may be provided on insulating materials 112. In some embodiments, conductive materials 211 through 291 are metal or a conductive material such as polysilicon.

The same structure as that on first and second doping regions 311 and 312 may be provided between second and third doping regions 312 and 313. Between second and third doping regions 312 and 313, there may be provided insulating materials 112 extending along the first direction, pillars 113 sequentially disposed in the first direction and passing through insulating materials 112 along the second direction, insulating film 116 provided on exposed surfaces of pillars 113 and insulating materials 112, and conductive materials 212 through 292 extending along the first direction.

The same structure as that on first and second doping regions 311 and 312 may be provided between third and fourth doping regions 313 and 314. Between third and fourth doping regions 313 and 314, there may be provided insulating materials 112 extending along the first direction, pillars 113 sequentially disposed in the first direction and passing through insulating materials 112 in the third direction, insulating film 116 provided on the exposed surfaces of insulating materials 112 and pillars 113, and first conductive materials 213 through 293 extending along the first direction.

Drains 320 may be provided on pillars 113, respectively. In some embodiments, drains 320 comprise a second-type silicon material, e.g., n-type silicon material. Hereinafter, it is assumed that drains 320 comprise n-type silicon material. However, drains 320 are not limited thereto. In some embodiments, a width of each of drains 320 may be wider than that of a corresponding one of pillars 113. For example, each of drains 320 may be provided on a corresponding one of pillars 113 to have a pad shape.

Conductive materials 331 through 333 extending along the third direction are provided on drains 320. Conductive materials 331 through 333 are sequentially disposed along the first direction. Conductive materials 331 through 333 are connected to drains 320 of corresponding regions, respectively. In some embodiments, drains 320 and second conductive material 333 extending along the third direction are connected through contact plugs. In some embodiments, conductive materials 331 through 333 comprise a metal material or another conductive material such as polysilicon.

In FIGS. 8 and 9, each of pillars 113 forms a string together with an adjacent region of an insulating film 116 and an adjacent region among conductive materials 211 through 291, 212 through 292, and 213 through 293 extending along the first direction. For example, each of pillars 113 may form a NAND string NS together with an adjacent region of an insulating film 116 and an adjacent region among conductive materials 211 through 291, 212 through 292, and 213 through 293 extending along the first direction. NAND string NS may comprise transistor structures TS.

Surface layer 114 of pillars 113, formed of p-type silicon, acts as a body. First sub-insulating film 117 acts as a tunneling insulating film. For example, first sub-insulating film 117 adjacent to one of pillars 113 may comprise a thermal oxide layer.

Second sub-insulating film 118 acts as a charge storage film. For example, second sub-insulating film 118 may act as a charge trap layer. For example, second sub-insulating film 118 may comprise a nitride layer or a metal oxide layer (e.g., an aluminum oxide layer, a hafnium oxide layer, or the like).

Third sub-insulating film 119 adjacent to a conductive material 233 acts as a blocking insulating film. In some embodiments, third sub-insulating film 119 adjacent to a conductive material 233 extending along a first direction may be a single layer or a multi-layer. Third sub-insulating film 119 may be a high dielectric layer (e.g., an aluminum oxide layer or a hafnium oxide layer) having a larger dielectric constant compared with the first and second sub-insulating films 117 and 118.

Conductive material 233 may serve as a gate (or a control gate). That is, conductive material 233 serving as a gate (or a control gate), third sub-insulating film 119 serving as the blocking insulating film, second sub-insulating film 118 serving as the charge storage layer, first sub-insulating film 117 serving as the tunneling insulation layer, and surface layer 114 serving as a body may form a transistor (or, a memory cell transistor structure). In some embodiments, the first through third sub-insulating films 117 through 119 may form oxide-nitride-oxide (ONO). Below, it is assumed that surface layer 114 of pillars 113 serves as a second-direction body.

A memory block BLKi may comprise pillars 113. That is, memory block BLKi may comprise NAND strings NS. In detail, memory block BLKi may comprise NAND strings NS extending along a second direction (or, a direction vertical to a substrate).

Each NAND string NS may comprise transistor structures TS that are disposed along a second direction. At least one of transistor structures TS of each NAND string NS may serve as a string selection transistor SST. At least one of transistor structures TS of each NAND string NS may serve as a ground selection transistor GST.

Gates (or control gates) may correspond to conductive materials 211 through 291, 212 through 292, and 213 through 293 extending along a first direction. That is, the gates (or the control gates) may be extended in the first direction to form two selection lines (e.g., at least one string selection line SSL and at least one ground selection line GSL) and word lines extending along the first direction.

Conductive materials 331 through 333 extending in a third direction may be connected to ends of NAND strings NS, respectively. Conductive materials 331 through 333 may act as bit lines BL. In memory block BLK1, one bit line may be connected with NAND strings. First through fourth doping regions 311 through 314 of second-type and extending in the first direction may be provided to other ends of NAND strings NS, respectively. First through fourth doping regions 311 through 314 of second-type may serve as common source lines CSL.

As indicated by the foregoing, memory block BLKi may comprise NAND strings that extend in a direction (i.e., the second direction) vertical to substrate 111, and may be a NAND flash memory block (e.g., a charge trap type) in which NAND strings NS may be connected to one bit line BL.

FIGS. 7 through 9 were described under the assumption that conductive materials 211 through 291, 212 through 292, and 213 through 293 extending along the first direction are formed at nine layers. However, the inventive concept is not limited thereto. For example, conductive lines extending along the first direction may be provided at 8, 16, or plural layers. That is, one NAND string may comprise 8, 16, or plural transistors.

FIGS. 8 through 9 were described under the assumption that three NAND strings NS are connected to a bit line. However, the inventive concept is not limited thereto. In some embodiments, in a memory block BLKi, m NAND strings NS may be connected to a bit line BL. At this time, the number of conductive materials 211 through 291, 212 through 292, and 213 through 293 extending along the first direction and the number of common source lines formed by first through fourth doping regions 311 through 314 may be adjusted according to the number of NAND strings NS connected to a bit line BL.

FIGS. 8 through 9 were described under the assumption that three NAND strings NS are connected to a conductive material extending along the first direction. However, the inventive concept is not limited thereto. For example, n NAND strings NS may be connected to a conductive material extending along the first direction. At this time, the number of bit lines formed by conductive materials 331 through 333 may be adjusted according to the number of NAND strings connected to a bit line extending along the first direction.

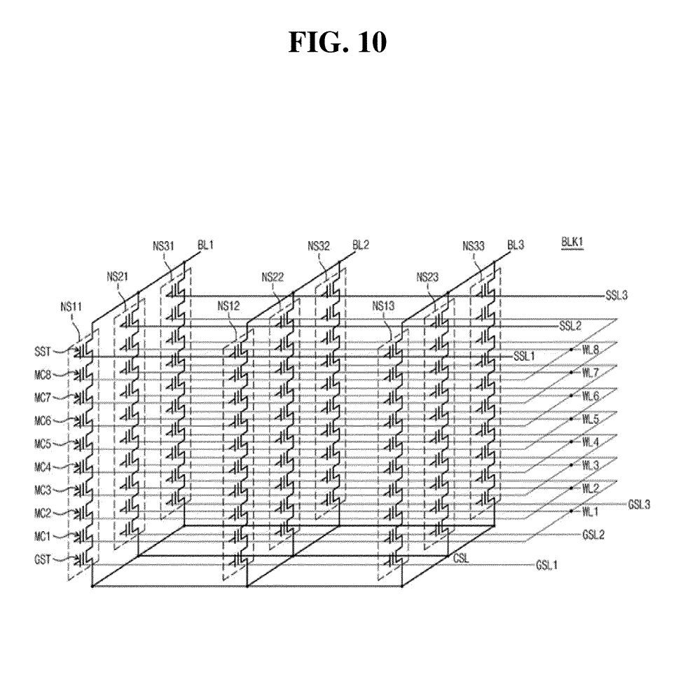

FIG. 10 is an equivalent circuit diagram of a memory block described with reference to FIGS. 7 through 9.

Referring to FIGS. 7 through 10, NAND strings NS11, NS21, and NS31 may be provided between a first bit line BL1 and a common source line CSL. NAND strings NS12, NS22, and NS32 may be provided between a second bit line BL2 and the common source line CSL. NAND strings NS13, NS23, and NS33 may be provided between a third bit line BL3 and the common source line CSL. First through third bit lines BL1 through BL3 may correspond to conductive materials 331 through 333 extending in the third direction, respectively.

A string selection transistor SST of each NAND string NS may be connected to a corresponding bit line BL. A ground selection transistor GST of each NAND string NS may be connected to the common source line CSL. In each NAND string NS, memory cells MC may be provided between string selection transistor SST and ground selection transistor GST.

Below, NAND strings NS may be designated by row and by column. NAND strings NS connected to one bit line in common may form one column. For example, NAND strings NS11 through NS31 connected to the first bit line BL1 may correspond to a first column. NAND strings NS12 through NS32 connected to the second bit line BL2 may correspond to a second column. NAND strings NS13 through NS33 connected to the third bit line BL3 may correspond to a third column. NAND strings NS connected to one string selection line SSL may form one row. For example, NAND strings NS11 through NS13 connected to a first string selection line SSL1 may form a first row. NAND strings NS21 through NS23 connected to a second string selection line SSL2 may form a second row. NAND strings NS31 through NS33 connected to a third string selection line SSL3 may form a third row.

In each NAND string NS, a height may be defined. In some embodiments, in each NAND string NS, a memory cell MC1 adjacent to ground selection transistor GST may be defined to have a height of 1. In each NAND string NS, a height of a memory cell may increase in inverse proportion to a distance from a string selection transistor SST. In each NAND string NS, a memory cell MC7 adjacent to string selection transistor SST may be defined to have a height of 7.

NAND strings in the same row may share the string selection line SSL. NAND strings in different rows may be connected to different string selection lines SSL1, SSL2, and SSL3, respectively. In each NAND string NS in the same row, memory cells having the same height may share a word line WL. At the same height, word lines WL connected to memory cells of NAND strings in different rows may be connected in common. Word line WL may be configured to be the memory cell layer. The block comprises memory cell layers stacked on a substrate and are electrically connected with other word lines Thus, treating the word line connected to the bad memory cell as the bad area may be treating the memory cell layer comprising the bad memory cell as the bad area.

In the same row of NAND strings NS, ground selection transistors GST may share a ground selection line GSL. In different rows of NAND strings NS, ground selection transistors GST may share the ground selection line GSL. That is, NAND strings NS11 through NS13, NS21 through NS23, and NS31 through NS33 may be connected in common to the ground selection line GSL.

Common source line CSL may be connected in common to NAND strings NS. For example, first through fourth doping regions 311 through 314 may be interconnected at an active region of a substrate 111. For example, first through fourth doping regions 311 through 314 may be connected to an upper layer via contacts. First through fourth doping regions 311 through 314 may be connected in common at the upper layer.

As illustrated in FIG. 10, word lines placed at the same height may be connected in common. Thus, where a word line placed at a specific height is selected and all NAND strings connected with the selected word line may be selected. NAND strings in different rows may be connected to different string selection lines. Thus, NAND strings in an unselected row from among NAND strings connected with the same word line may be separated from a corresponding bit line by selecting the string selection lines SSL1 through SSL3. That is, a row of NAND strings may be selected by selecting and unselecting the string selection lines SSL1 through SSL3. A column of NAND strings in a selected row may be selected by selecting bit lines BL1 through BL3.

Bad area management unit 1230 may effectively increase the available data storage capacity provided by the memory cell array(s) of non-volatile memory device 1100 by minimizing or reducing the size of designated bad areas.

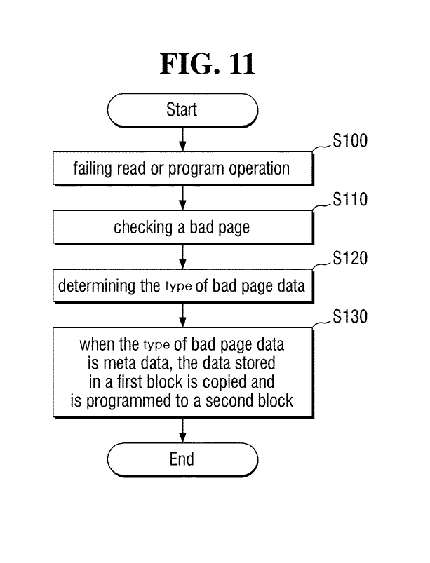

FIG. 11 is a flowchart illustrating a method of operating a memory controller according to an embodiment of the inventive concept.

Referring to FIG. 11, the non-volatile memory device detects a failure of a read or program operation (S100). The memory controller checks the bad page where program or read operation failed (S110). And the memory controller determines what type of data the bad page stores (S120). The memory controller copies data stored in the first block and program the copied data into the second block where data of the bad page is meta data (S130). Then, the first block is erased and become a free block where user data is programmed.

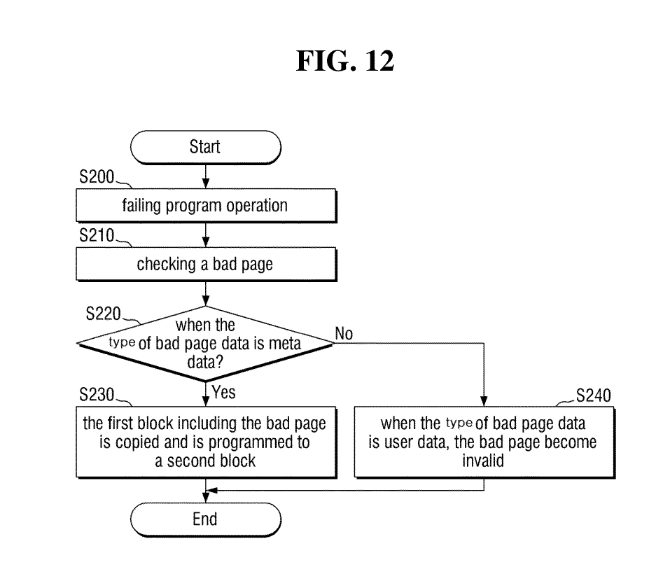

FIG. 12 is a flowchart illustrating a method of operating a memory controller according to an embodiment of the inventive concept.

Referring to FIG. 12, a failure occurs in program operation of a non-volatile memory device (S200), and a memory controller checks a resulting bad page (S210). Then, the memory controller determines whether data of the bad page is meta data (S220). Where data of the bad page is meta data, the first block comprising the bad page is copied and copied data is programmed to the second block (S230). Otherwise, where data of the bad page is not meta data but user data, the bad page is discarded (S240). The discarded bad page address may be stored in RAM and the discarded bad page is not used for program or read operation.

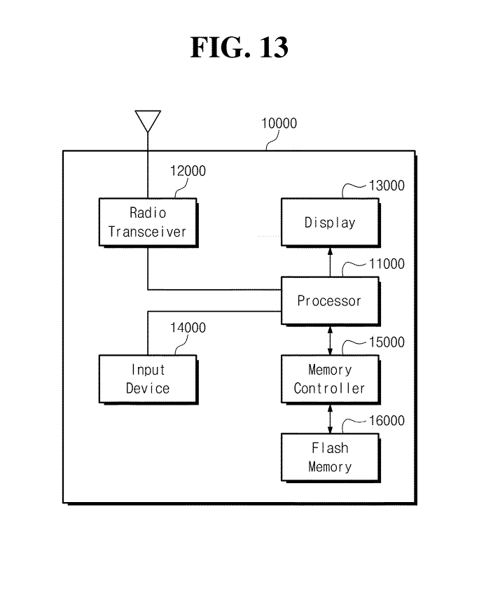

FIG. 13 is a block diagram illustrating an electronic device 10000 comprising a non-volatile memory device according to an embodiment of the inventive concept.

Referring to FIG. 13, electronic device 10000 such as a cellular phone, a smart phone, or a tablet PC may comprise a non-volatile memory device 16000 formed of a flash memory device and a memory controller 15000 controlling an operation of non-volatile memory device 16000.

Non-volatile memory device 16000 may be a non-volatile memory device as described in relation to FIG. 1, for example. Non-volatile memory device 16000 may be configured to verify programming of first data pattern using a first memory cell storing the first data pattern, a second memory cell programmed using a program voltage, and a verification voltage corresponding to the first data pattern. Where a verification result of the first memory cell indicates a pass, programming of the second memory cell may be ended.

Memory controller 15000 may correspond to a memory controller illustrated in FIG. 1, for example. Memory controller 15000 may be controlled by a processor 11000 controlling an overall operation of electronic device 10000.

Data stored in non-volatile memory device 16000 may be displayed via a display 13000 under the control of memory controller 15000 operating under the control of processor 11000.

A radio transceiver 12000 transmits and receives a radio signal via an antenna. For example, radio transceiver 12000 may convert a radio signal received via the antenna to a signal suitable for processor 11000 to process. Processor 11000 may process a signal output from radio transceiver 12000, and the processed signal may be stored in non-volatile memory device 16000 via memory controller 15000 or displayed via display 13000.

Radio transceiver 12000 may convert a signal from processor 11000 to a radio signal to output it to an external device via the antenna. An input device 14000 may be a device capable of receiving a control signal for controlling an operation of processor 11000 or data to be processed by processor 11000. Input device 14000 may comprise a pointing device such as a touch pad or a computer mouse, a keypad, or a keyboard.

Processor 11000 may control display 13000 so as to display data output from non-volatile memory device 16000, a radio signal from radio transceiver 12000, or data from input device 14000.

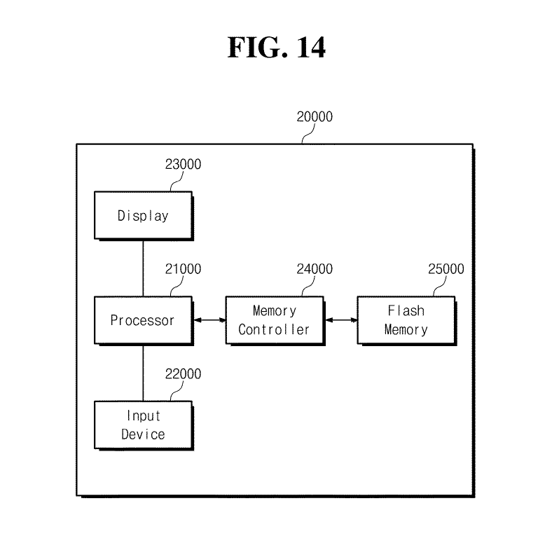

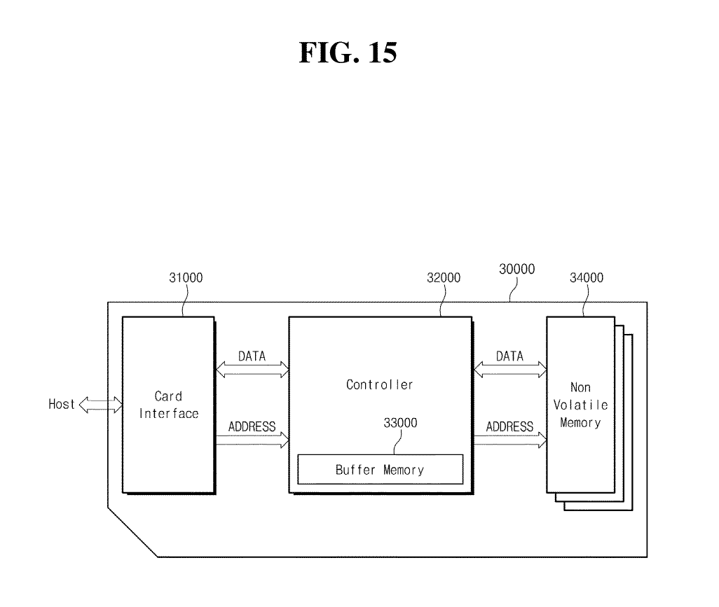

FIG. 14 is a block diagram illustrating an electronic device 20000 comprising a memory controller and a non-volatile memory device according to an embodiment of the inventive concept. Electronic device 20000 may be a data processing device such as a personal computer, a tablet computer, a net-book, an e-reader, a PDA, a PMP, an MP3 player, or an MP4 player, and may comprise a non-volatile memory device 25000 such as a flash memory device and a memory controller 24000 controlling an operation of non-volatile memory device 25000.

Non-volatile memory device 25000 may correspond to a non-volatile memory device described in relation to FIG. 1, for example. Non-volatile memory device 25000 may be configured to verify programming of first data pattern using a first memory cell storing the first data pattern, a second memory cell programmed using a program voltage, and a verification voltage corresponding to the first data pattern. Where a verification result of the first memory cell indicates a pass, programming of the second memory cell may be ended.

Memory controller 24000 may correspond to a memory controller illustrated in FIG. 1. Electronic device 20000 may comprise a processor 21000 controlling an overall operation of electronic device 20000. Memory controller 24000 may be controlled by processor 21000. Processor 21000 may display data, stored in a non-volatile memory device, via a display according to an input signal generated by an input device 22000. For example, input device 22000 may be formed of a pointing device such as a touch pad or a computer mouse, a keypad, or a keyboard.

FIG. 15 is a block diagram illustrating an electronic device comprising a non-volatile memory device according to an embodiment of the inventive concept.

Referring to FIG. 15, an electronic device 30000 comprises a card interface 31000, a memory controller 32000, and at least one non-volatile memory device 34000, for example, a flash memory device.

Electronic device 30000 may exchange data with a host via card interface 31000. In some embodiments, card interface 31000 may be an SD card interface or an MMC interface. However, example embodiments of inventive concepts are not limited thereto. Card interface 31000 may exchange data between the host and memory controller 32000 according to the communication protocol of the host capable of communicating with electronic device 30000.

Memory controller 32000 may control an overall operation of electronic device 30000, and may control data exchange between card interface 31000 and non-volatile memory device 34000. A buffer memory 33000 of memory controller 32000 may buffer data transferred between card interface 31000 and the at least one non-volatile memory device 34000.

Memory controller 32000 is connected to card interface 31000 and non-volatile memory device 34000 via a data bus and an address bus. In some embodiments, memory controller 32000 may receive an address of data to be read or written via the address bus from card interface 31000 to send it to the at least one non-volatile memory device 34000. Memory controller 32000 receives and sends data to be read or written via the data bus connected to card interface 31000 or the at least one non-volatile memory device 34000.

The at least one non-volatile memory device 34000 may correspond to a non-volatile memory device described in relation to FIG. 1, for example. The at least one non-volatile memory device 34000 may be configured to verify programming of first data pattern using a first memory cell storing the first data pattern, a second memory cell programmed using a program voltage, and a verification voltage corresponding to the first data pattern. Where a verification result of the first memory cell indicates a pass, programming of the second memory cell may be ended. Memory controller 32000 may correspond to a memory controller illustrated in FIG. 1, for example.

Where electronic device 30000 in FIG. 15 is connected to a host such as a PC, a tablet PC, a digital camera, a digital audio player, a cellular phone, a console video game hardware, or a digital set-top box, the host may send or receive data stored in non-volatile memory device 34000 via card interface 31000 and memory controller 32000.

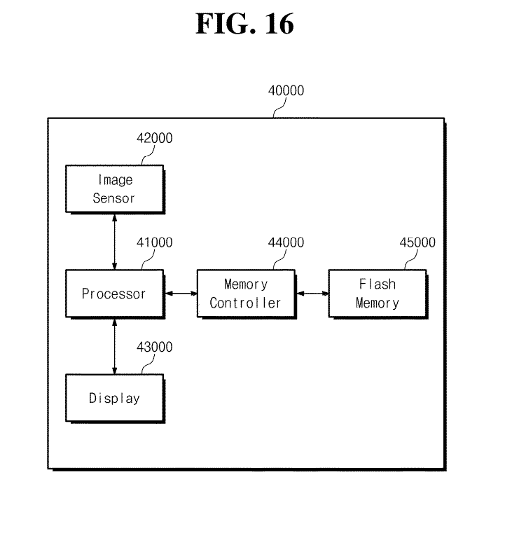

FIG. 16 is a block diagram illustrating an electronic device comprising a memory controller and a non-volatile memory device according to an embodiment of the inventive concept.

Referring to FIG. 16, an electronic device 40000 comprises a non-volatile memory device 45000 such as a flash memory device, a memory controller 44000 controlling a data processing operation of non-volatile memory device 45000, and a processor 41000 controlling an overall operation of electronic device 40000.

Non-volatile memory device 45000 may correspond to a non-volatile memory device described in relation to FIG. 1, for example. Non-volatile memory device 45000 may be configured to verify programming of first data pattern using a first memory cell storing the first data pattern, a second memory cell programmed using a program voltage, and a verification voltage corresponding to the first data pattern. Where a verification result of the first memory cell indicates a pass, programming of the second memory cell may be ended. Memory controller 44000 may correspond to a memory controller illustrated in FIG. 1.

An image sensor 42000 of electronic device 40000 may convert an optical signal to a digital signal, and the digital signal may be stored in non-volatile memory device 45000 or displayed via a display 43000 under the control of processor 41000.

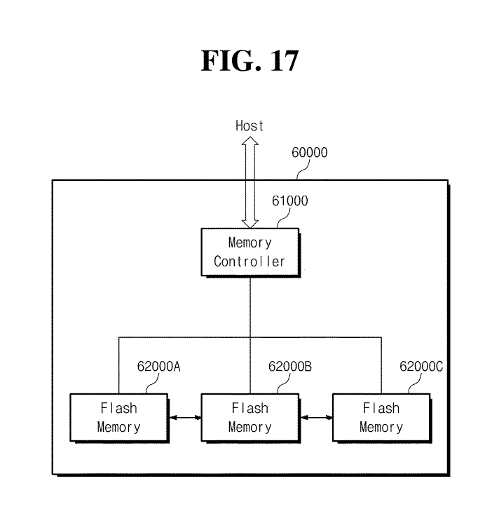

FIG. 17 is a block diagram illustrating an electronic device comprising a memory controller and non-volatile memory devices according to an embodiment of the inventive concept.

Referring to FIG. 17, an electronic device 60000 may be implemented by a data storage device such as a Solid State Drive (SSD). Electronic device 60000 may comprise non-volatile memory devices 62000A, 62000B, and 62000C and a memory controller 61000 controlling a data processing operation of each of non-volatile memory devices 62000A, 62000B, and 62000C. Electronic device 60000 may be implemented by a memory system or a memory module.

Each of non-volatile memory devices 62000A, 62000B, and 62000C may be a non-volatile memory device described in FIGS. 1 and 2, for example. Each of non-volatile memory devices 62000A, 62000B, and 62000C may be configured to verify programming of first data pattern using a first memory cell storing the first data pattern, a second memory cell programmed using a program voltage, and a verification voltage corresponding to the first data pattern. Where a verification result of the first memory cell indicates a pass, programming of the second memory cell may be ended. Memory controller 61000 may correspond to a memory controller illustrated in FIG. 1. Memory controller 61000 may be provided at the interior or exterior of electronic device 60000.

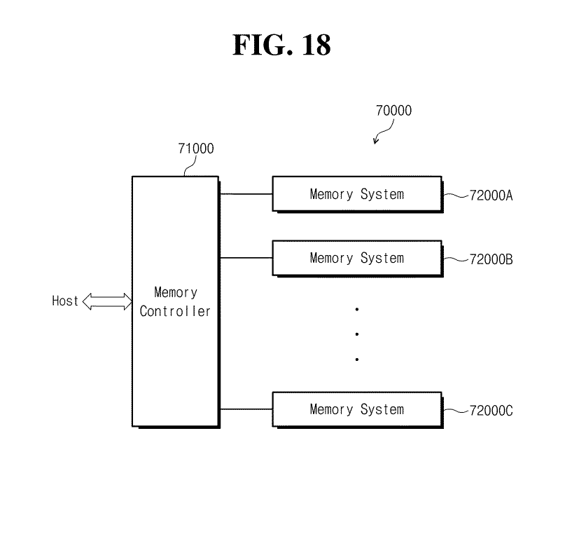

FIG. 18 is a block diagram illustrating a data processing system comprising an electronic device in FIG. 17.

Referring to FIGS. 22 and 23, a data storage device 70000 may be implemented by a Redundant Array of Independent Disks (RAID) system, and may comprise a RAID controller 71000 and memory systems 72000A to 72000C. Memory systems 72000A to 72000C may be an electronic device 60000 illustrated in FIG. 17. Memory systems 72000A to 72000C may constitute a RAID array. Data storage device 70000 may be implemented by a personal computer or an SSD.

During a program operation, RAID controller 71000 outputs program data from a host to one of memory systems 72000A to 72000C according to a RAID level, selected depending on RAID level information from the host, from among multiple RAID levels.

During a read operation, RAID controller 71000 provides the host with data read from one of memory systems 72000A to 72000C according to a RAID level, selected depending on RAID level information from the host, from among multiple RAID levels.

The foregoing is illustrative of embodiments and is not to be construed as limiting thereof. Although a few embodiments have been described, those skilled in the art will readily appreciate that many modifications are possible in the embodiments without departing from the scope of the inventive concept as defined in the claims.

What is claimed is:

1. A method of controlling a non-volatile memory device, comprising:
detecting a bad page in a first block of the non-volatile memory device; and
as a consequence of detecting the bad page, copying meta data stored in valid pages of the first block and original meta data corresponding to the bad page, programming the copied meta data to a second block of the non-volatile memory device, erasing the first block, and thereafter programming user data in the first block.

2. The method of claim 1, further comprising updating address information of a free block table to reflect the erasing of the first block.

3. The method of claim 1, wherein the bad page is a read failed page.

4. The method of claim 3, wherein meta data stored in the first block is also stored in a third block of the non-volatile memory device, and programming the original meta data comprises copying the original data stored in the third block and program the original data into the second block.

5. The method of claim 4, wherein the original data is provided by a host.

6. The method of claim 1, wherein the bad page is a program failed page.

7. A method of controlling a non-volatile memory device, comprising:
identifying a bad page of the non-volatile memory device based on a program or read failure;
determining a type of data associated with the bad page; and
selectively performing bad page management or bad block management according to the determined type of data.

8. The method of claim 7, wherein selectively performing bad page management or bad block management comprises performing bad page management where the determined type of data is user data, and performing bad block management where the determined type of data is meta data.

9. The method of claim 7, wherein the bad block management comprises copying valid data from a first block including the bad page, and programming the copied data and original meta data to a second block.

10. The method of claim 9, wherein the second block is a free block.

11. The method of claim 9, further comprising updating an address map to reflect the programming of the copied to the second block.

12. The method of claim 9, further comprises, after the bad block management, erasing the first block and thereafter programming user data to the first block.

13. The method of claim 12, further comprising updating a free block table to reflect the erasing of the first block.

14. The method of claim 7, wherein the bad page management comprises invalidating the bad page.

15. The method of claim 7, wherein the bad page is an error correction code (ECC) decoding failed page.

16. The method of claim 7, wherein the bad page is a verify operation failed page.

17. A memory system, comprising:
a non-volatile memory device comprising a memory cell array stacked on a substrate and comprising at least one meta data block and at least one user data block; and
a memory controller that controls the non-volatile memory device, the memory controller comprising a bad area management unit configured to manage a bad area of both the at least one meta data block and the at least one user data block, wherein the bad area management unit is configured to convert a designated meta data block among the at least one meta data block into a user data block as a consequence of detecting a bad page in the designated meta data block.

18. The memory system of claim 17, wherein the non-volatile memory comprises a free block and the bad area management unit is configured to copy the designated meta data block into the free block.

19. The memory system of claim 17, wherein the memory controller is configured to identify a bad page of the non-volatile memory device based on a program or read failure, determine a type of data associated with the bad page, and selectively perform bad page management or bad block management according to the determined type of data.

20. The memory system of claim 17, wherein the conversion of the designated meta data block into the user data block comprises copying valid data from the meta data block to a different block, erasing the designated meta data block, redesignating the meta data block as a user data block, and thereafter storing user data in the redesignated meta data block.
